(19) United States
(12) Patent Application Publication
(10) Pub. No.: US 2025/0350271 A1
(43) Pub. Date: Nov. 13, 2025

(54) CLOCK SIGNAL GENERATOR AND OPERATION METHOD THEREOF

(71) Applicant: SAMSUNG ELECTRONICS CO., LTD., Suwon-si (KR)

(72) Inventors: Suneui Park, Suwon-si (KR); Yongsun Lee, Suwon-si (KR); Jaewoo Park, Suwon-si (KR); Myoungbo Kwak, Suwon-si (KR)

(21) Appl. No.: 18/986,370

(22) Filed: Dec. 18, 2024

(30) Foreign Application Priority Data
May 13, 2024 (KR) 10-2024-0062610

(51) Int. Cl. H03K 5/131

(52) U.S. Cl. CPC H03K 5/131

(57) ABSTRACT

The present disclosure relates to clock signal generators and operation methods of the clock signal generators. An example clock signal generator includes a frequency calibrator and an oscillator. The frequency calibrator is configured to identify at least one digital code corresponding to an overlapping frequency band among a plurality of digital codes for controlling values of a plurality of elements included in the oscillator, and identify a plurality of first digital codes into which the at least one digital code is filtered from the plurality of digital codes. The oscillator is configured to generate a clock signal of a frequency based on the plurality of elements having values corresponding to each of at least some of the plurality of first digital codes.

### CROSS-REFERENCE TO RELATED APPLICATION

This application claims the benefit of Korean Patent Application No. 10-2024-0062610, filed on May 13, 2024, in the Korean Intellectual Property Office, the disclosure of which is incorporated herein by reference.

### BACKGROUND

An oscillator can generate a signal of a predetermined frequency. In order for the oscillator to generate the signal of the predetermined frequency, an initial frequency of the oscillator is to be set close to the predetermined frequency. In this regard, a frequency calibrator can calibrate a frequency of the oscillator so that the initial frequency of the oscillator is set close to the predetermined frequency. However, it may take a long time for the frequency calibrator to calibrate the frequency of the oscillator.

### SUMMARY

The present disclosure relates to a clock signal generator including a frequency calibrator for minimizing time to calibrate a frequency of an oscillator and an operation method thereof.

The technical problems to be solved by the present disclosure are not limited to the technical problems described above, and other technical problems may be inferred from the following example implementations.

In some implementations, a clock signal generator includes an oscillator; and a frequency calibrator configured to identify at least one digital code among a plurality of digital codes, the at least one digital code corresponding to an overlapping frequency band, the plurality of digital codes being configured to control values of a plurality of elements included in the oscillator, and identify a plurality of first digital codes, wherein the at least one digital code is filtered from the plurality of digital codes; and wherein the oscillator is configured to generate a clock signal of a frequency based on the plurality of elements, the plurality of elements having values corresponding to each of at least some of the plurality of first digital codes.

In some implementations, a frequency calibrator includes a digital code identifier configured to identify at least one digital code based on one or more digital codes and an output value among a plurality of digital codes, the plurality of digital codes being configured to control values of a plurality of elements included in an oscillator, the at least one digital code corresponding to an overlapping frequency band, the output value being outputted from a counter based on a clock signal of a frequency being inputted to the counter, the clock signal of the frequency being based on the plurality of elements having values corresponding to each of the one or more digital codes; and an automatic frequency controller configured to identify a plurality of first digital codes, wherein the at least one digital code is filtered from the plurality of digital codes, and transmit at least some of the plurality of first digital codes to the oscillator.

In some implementations, an operation method of a clock signal generator includes identifying at least one digital code among a plurality of digital codes, the at least one digital code corresponding to an overlapping frequency band, the plurality of digital codes being configured to control values of a plurality of elements included in an oscillator; identifying a plurality of first digital codes, wherein the at least one digital code is filtered from the plurality of digital codes; and generating a clock signal of a frequency based on the plurality of elements, the plurality of elements having values corresponding to each of at least some of the plurality of first digital codes.

In some implementations, a non-transitory computer-readable recording medium having a program for executing the operation method on a computer is provides.

Additional aspects of example implementations will be set forth in part in the description which follows and, in part, will be apparent from the description, or may be learned by practice of the disclosure.

In some implementations, one or more of the following effects may be obtained.

In some implementations, a clock signal generator may identify at least one digital code corresponding to an overlapping frequency band based on one or more digital codes among a plurality of digital codes for controlling values of a plurality of elements included in an oscillator. Thus, by identifying a plurality of first digital codes into which the at least one digital code is filtered from the plurality of digital codes, the clock signal generator may not transmit the at least one digital code corresponding to the overlapping frequency band to the oscillator and may transmit at least some of the plurality of first digital codes alone to the oscillator. Accordingly, it is possible to minimize the time to calibrate a frequency of the oscillator and it is also possible to minimize a power amount consumed for a frequency of a signal outputted from the clock signal generator to be synchronized with a target frequency.

Additional features and advantages of the present disclosure will be set forth in the description which follows, and in part will be apparent from the description, or may be learned by practice of the present disclosure. The objectives and other advantages of the present disclosure will be realized and attained by the structure particularly pointed out in the written description and claims hereof as well as the appended drawings.

### BRIEF DESCRIPTION OF THE DRAWINGS

These and/or other aspects, features, and advantages of the present disclosure will become apparent and more readily appreciated from the following description of example implementations, taken in conjunction with the accompanying drawings.

FIG. 1 is a diagram for illustrating an example of a clock signal generator.

FIG. 2 is a diagram for illustrating an example of a frequency calibrator.

FIG. 3 is a diagram for illustrating an example of a clock signal generator in more detail.

FIG. 4 is a diagram for illustrating an example of an operation of a digital code identifier in more detail.

FIG. 5 is a diagram for illustrating an example of an operation of an automatic frequency controller in more detail.

FIG. 6 is a diagram for illustrating an example of an operation of an oscillator controller in more detail.

FIG. 7 is a diagram for illustrating an example of a table that indicates a plurality of digital codes and a frequency of a clock signal corresponding to each of the plurality of digital codes when a target frequency is included in a low-frequency band.

FIG. 8 is a graph for illustrating an example of a manner of identifying an end digital code for generating a clock signal of a frequency within a set range from a target frequency as increasing a value of a digital code.

FIG. 9 is a graph for illustrating an example of a manner of identifying an end digital code for generating a clock signal of a frequency within a set range from a target frequency as decreasing a value of a digital code.

FIG. 10 is a diagram for illustrating an example of a table that indicates a plurality of digital codes and a frequency of a clock signal corresponding to each of the plurality of digital codes when a target frequency is included in a high-frequency band.

FIG. 11 is a graph for illustrating an example of a manner of identifying an end digital code for generating a clock signal of a frequency within a set range from a target frequency as increasing a value of a digital code.

FIG. 12 is a diagram for illustrating an example of a table that indicates a plurality of digital codes and a frequency of a clock signal corresponding to each of the plurality of digital codes when a plurality of upper bits related to a first element are provided.

FIG. 13 is a graph for illustrating an example of a manner of identifying an end digital code for generating a clock signal of a frequency within a set range from a target frequency as increasing a value of a digital code when a plurality of overlapping frequency bands are provided.

FIG. 14 is a flowchart for illustrating an example of an operation method of a clock signal generator.

### DETAILED DESCRIPTION

Terms used in the example implementations are selected from currently widely used general terms when possible while considering the functions in the present disclosure. However, the terms may vary depending on the intention of a person skilled in the art, precedents, the emergence of new technology, and the like. Further, in certain cases, there are also terms arbitrarily selected by the applicant, and in these cases, the meaning will be described in detail in the corresponding descriptions. Therefore, the terms used in the present disclosure should be defined based on the meaning of the terms and the overall context of the present disclosure, rather than the simple names of the terms.

Throughout the specification, when a part is described as “comprising or including” a component, it does not exclude another component but may further include another component unless otherwise stated. Furthermore, terms such as “ . . . unit,” “ . . . part,” and “ . . . module” described in the specification mean a unit that processes at least one function or operation, which may be implemented as hardware, software, or a combination thereof.

Hereinafter, example implementations of the present disclosure will be described in detail with reference to the accompanying drawings so that those of ordinary skill in the art to which the present disclosure pertains may easily implement them. However, the present disclosure may be implemented in multiple different forms and is not limited to the example implementations described herein.

Hereinafter, example implementations of the present disclosure will be described in detail with reference to the accompanying drawings.

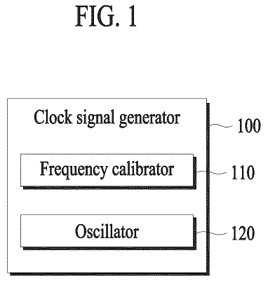

FIG. 1 is a diagram for illustrating an example of a clock signal generator.

Referring to FIG. 1, a clock signal generator 100 may include a frequency calibrator 110 and an oscillator 120. Here, the clock signal generator 100 may be a device for generating a clock signal of a predetermined target frequency. More specifically, the clock signal generator 100 may be a device for generating a clock signal of a high-frequency band equal to or higher than a set value (for example, 10 gigahertz (GHz)). For example, the clock signal generator 100 may correspond to any one of a phase-locked loop (PLL) for keeping a frequency or a phase of an output signal fixed and a clock and data recovery (CDR) which is used to reconfigure the frequency of an original signal for accurate regeneration or recovery of the original signal but is not limited thereto.

In some implementations, the clock signal generator 100 may be included in various devices. The clock signal generator 100 may be included in a serialization and deserialization (SERDED) system for generating a high-frequency clock signal. Alternatively, the clock signal generator 100 may be included in an interface device, such as Peripheral Component Interconnect Express (PCIe) Gen series (for example, PCIe Gen6 and PCIe Gen7), MPHY Gear6, WiFi transceiver, and 5G transceiver, but is not limited thereto.

The frequency calibrator 110 may be a device for calibrating a frequency of a clock signal generated in the oscillator 120. More specifically, the frequency calibrator 110 may be a device for appropriately adjusting values of a plurality of elements included in the oscillator 120, in order to calibrate a frequency of a clock signal generated in the oscillator 120 to be within a set range from a target frequency. Here, the target frequency may be a frequency on target to be generated in the clock signal generator 100, and the set range may be a lock range which allows a frequency of a clock signal to converge on the target frequency. The frequency calibrator 110 may be implemented by a processor.

A digital code may be used to control values of the plurality of elements included in the oscillator 120. Here, the digital code may be a frequency control word (FCW) but is not limited thereto. When the plurality of elements include a first element and a second element, the digital code may consist of at least one first bit related to the first element and at least one second bit related to the second element. For example, the at least one first bit may be a set number of upper bits and the at least one second bit may be a set number of lower bits, but example implementations are not limited thereto.

The oscillator 120 may be a device for generating a clock signal. The oscillator 120 may include the plurality of elements and the frequency of the clock signal generated in the oscillator 120 may be based on the values of the plurality of elements. More specifically, the frequency of the clock signal generated in the oscillator 120 may be based on the plurality of elements having values corresponding to a digital code received from the frequency calibrator 110. When the oscillator 120 is an LC oscillator that includes an inductor and a capacitor, a value of the inductor and a value of the capacitor may correspond to a digital code, and the frequency of the clock signal generated in the oscillator 120 may be determined as

$$\frac{1}{2 π \sqrt{LC}} .$$

The oscillator 120 may be the LC oscillator but is not limited thereto. For example, the oscillator 120 may correspond to any one of an RC oscillator that includes resistance and a capacitor and a ring oscillator.

The plurality of elements included in the oscillator 120 may be elements with different physical properties. For example, any one element among the plurality of elements may have a characteristic that a performance of a corresponding element deteriorates in a low-frequency band and another element may have a characteristic that a performance of the corresponding element deteriorates in a high-frequency band. With regard thereto, when the values of the plurality of elements are set in an appropriate range, the frequency of the clock signal generated in the oscillator 120 may be set close to the target frequency while the performance of the oscillator 120 may be optimized. With regard thereto, even though the oscillator 120 is the LC oscillator, when a high-frequency clock signal is generated with the value of the capacitor alone adjusted, the performance of the oscillator 120 may greatly deteriorate. In this case, by appropriately adjusting the value of the capacitor and the value of the inductor together, deterioration in the performance of the oscillator 120 may be minimized while a clock signal of a frequency close to a predetermined frequency which is high-frequency may be generated. Here, adjusting the value of the capacitor may be referred to as capacitive tuning, and adjusting the value of the inductor may be referred to as inductive tuning.

However, as the digital code is used to control the values of the plurality of elements included in the oscillator 120, nonlinearity may occur in the frequency of the clock signal generated in the oscillator 120. Further, for various reasons such as a difference between the design and the actual production of a device including the oscillator 120, a change in standards according to a use period of an element including the oscillator 120, and a difference in temperature coefficient by element, the frequency of the clock signal generated in the oscillator 120 may be partly different from a theoretical prediction value. With regard thereto, the values of the plurality of elements may be appropriately set to have a design margin so that frequencies of all frequency bands may be practically generated. In other words, the values of the plurality of elements may be set such that some frequencies of clock signals are overlapping.

Accordingly, when a plurality of digital codes are transmitted in sequence to the oscillator 120, a clock signal of a frequency included in an overlapping frequency band may be generated multiple times, and thus it may take much time to generate a clock signal of a frequency within the set range from the target frequency. In other words, transmitting the plurality of digital codes in sequence to the oscillator 120 without filtering may be inefficient. In particular, as a range of a target frequency of clock signals to be generated by the clock signal generator 100 is widened from the low-frequency band to the high-frequency band, a digital code composed of more bits may be used to adjust the values of the plurality of elements. Accordingly, the overlapping frequency band may largely increase. With regard thereto, before identifying a digital code corresponding to a clock signal of a frequency within the set range from the target frequency, the frequency calibrator 110 may identify at least one digital code corresponding to the overlapping frequency band based on one or more digital codes among a plurality of digital codes for controlling the values of the plurality of elements included in the oscillator 120 and identify a plurality of first digital codes into which the at least one digital code is filtered from the plurality of digital codes.

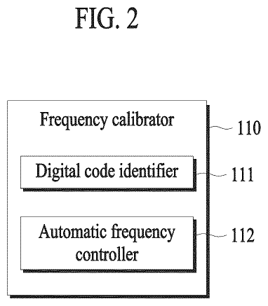

FIG. 2 is a diagram for illustrating an example of a frequency calibrator in more detail.

Referring to FIG. 2, the frequency calibrator 110 may include a digital code identifier 111 and an automatic frequency controller 112. The digital code identifier 111 and the automatic frequency controller 112 may be implemented by a processor.

In some implementations, the operation of the digital code identifier 111 and the operation of the automatic frequency controller 112 may be performed in turn. In other words, after at least one digital code is identified as the digital code identifier 111 operates, the automatic frequency controller 112 may identify a plurality of first digital codes by filtering the at least one digital code from a plurality of digital codes. Hereinafter, the operations of the digital code identifier 111 and the automatic frequency controller 112 are described.

The digital code identifier 111 may be a device for identifying at least one digital code corresponding to an overlapping frequency band. The digital code identifier 111 may identify one or more digital codes among the plurality of digital codes and identify the at least one digital code corresponding to the overlapping frequency band based on the one or more digital codes and an output value outputted from a counter in response to that a clock signal of a frequency based on a plurality of elements having values corresponding to each of the one or more digital codes is inputted to the counter.

The automatic frequency controller 112 may be a device for controlling a frequency of a clock signal generated in the oscillator 120 based on the plurality of first digital codes into which the at least one digital code identified is filtered from the plurality of digital codes. More specifically, the automatic frequency controller 112 may identify the plurality of first digital codes into which the at least one digital code is filtered from the plurality of digital codes and transmit at least some of the plurality of first digital codes to the oscillator 120. When a frequency of a clock signal based on the plurality of elements having values corresponding to a specific digital code is not within a set range from a target frequency, the automatic frequency controller 112 may retransmit another digital code to the oscillator 120 following the specific digital code. In contrast, when the frequency of the clock signal based on the plurality of elements having the values corresponding to the specific digital code is within the set range from the target frequency, the operation of the automatic frequency controller 112 may end, and values of the plurality of elements may be determined as the values corresponding to the specific digital code. In this case, the specific digital code may be referred to as an end digital code, and the frequency of the clock signal based on the plurality of elements having the values corresponding to the end digital code may be referred to as an initial frequency.

In some implementations, the frequency calibrator 110 may include not only the digital code identifier 111 and the automatic frequency controller 112 but also may further include other elements. For example, the frequency calibrator 110 may further include a multiplexer.

The multiplexer may be a device for transmitting any one digital code between a digital code received from the digital code identifier 111 and a digital code received from the automatic frequency controller 112 to the oscillator 120. As described, after the digital code identifier 111 operates, the automatic frequency controller 112 may operate. In other words, when the digital code identifier 111 operates, the multiplexer may transmit the digital code received from the digital code identifier 111 to the oscillator 120. Further, when the automatic frequency controller 112 operates, the multiplexer may transmit the digital code received from the automatic frequency controller 112 to the oscillator 120.

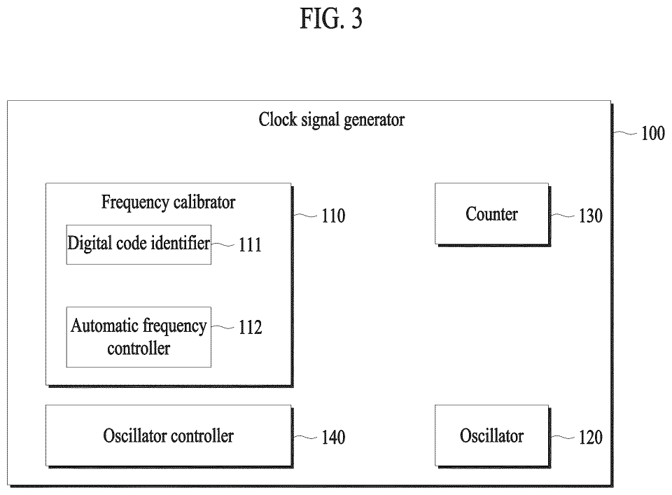

FIG. 3 is a diagram for illustrating an example of a clock signal generator in more detail.

Referring to FIG. 3, the clock signal generator 100 may include the frequency calibrator 110, the oscillator 120, a counter 130, and an oscillator controller 140.

The counter 130 may be a device used to count the number of waveforms of a clock signal that is inputted. More specifically, the counter 130 may calculate an output value corresponding to the number of waveforms of a clock signal received from the oscillator 120 which is received for a set time. For example, when the set time is 10 nanoseconds (ns) and the frequency of a clock signal is 20 GHz, the counter 130 may calculate 200 as the number of waveforms of the clock signal received for 10 ns. The counter 130 may transmit a calculated value to the frequency calibrator 110.

The oscillator controller 140 may be a device for controlling a frequency of a clock signal generated in the oscillator 120 to be a target frequency. Here, values of the plurality of elements included in the oscillator 120 may correspond to the end digital code. In other words, before the oscillator controller 140 operates, the frequency of a clock signal generated in the oscillator 120 may be the initial frequency. As the oscillator controller 140 operates, the oscillator controller 140 may transmit a control signal for controlling a frequency generated in the oscillator 120 to the oscillator 120. The oscillator 120 may generate a clock signal based on the control signal. The oscillator controller 140 may retransmit the control signal based on the generated clock signal to the oscillator 120. In other words, the clock signal generated in the oscillator 120 may be used as feedback for the oscillator controller 140 to generate the control signal. As the operation of generating the clock signal based on the control signal by the oscillator 120 and the operation of retransmitting the control signal based on the clock signal to the oscillator 120 by the oscillator controller 140 are performed repeatedly, the frequency of the clock signal generated in the oscillator 120 may converge on the target frequency. Accordingly, the clock signal generator 100 may generate a clock signal of the target frequency.

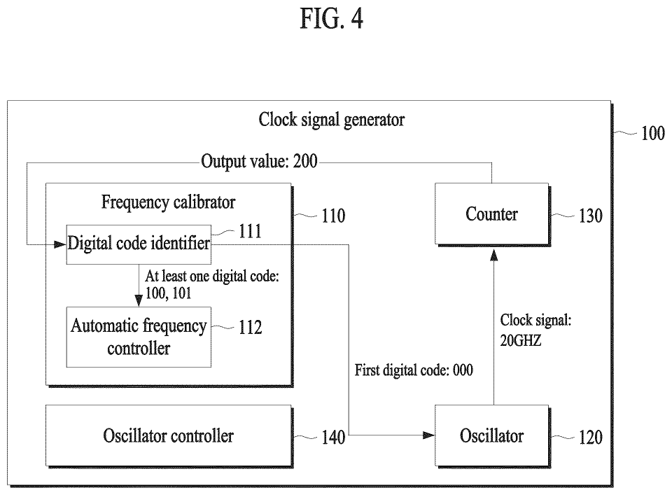

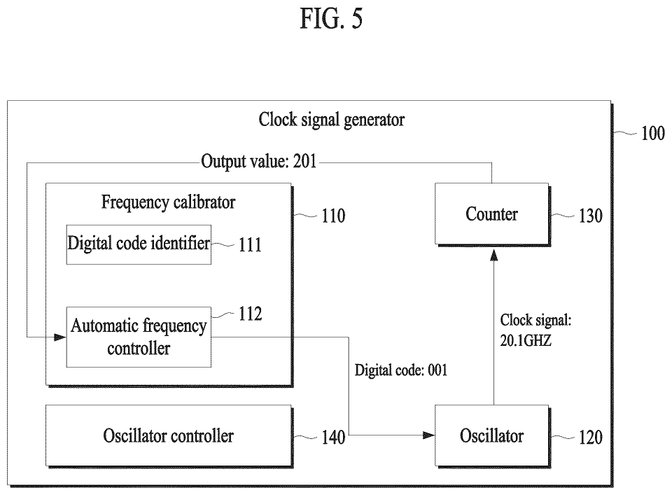

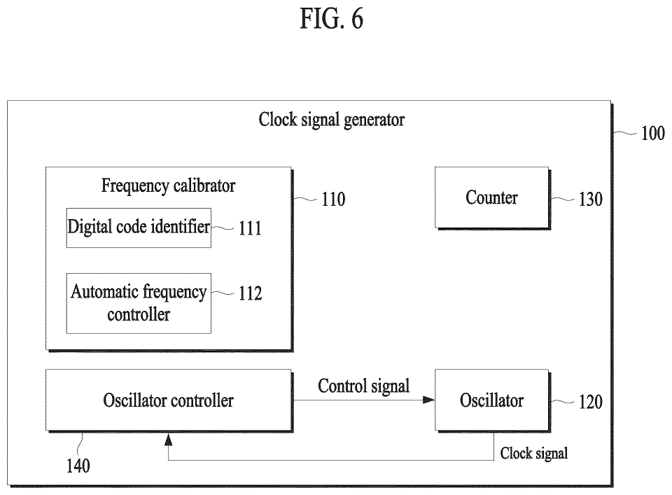

In some implementations, the operation of the digital code identifier 111, the operation of the automatic frequency controller 112, and the operation of the oscillator controller 140 may be performed in turn. With regard thereto, the operation of the digital code identifier 111 is described in detail in FIG. 4, the operation of the automatic frequency controller 112 is described in detail in FIG. 5, and the operation of the oscillator controller 140 is described in detail in FIG. 6.

FIG. 4 is a diagram for illustrating an example of an operation of a digital code identifier in more detail.

In some implementations, the digital code identifier 111 may identify one or more digital codes. Here, the one or more digital codes may be a digital code used to identify at least one digital code corresponding to an overlapping frequency band among a plurality of digital codes. In other words, the one or more digital codes may be used to identify the overlapping frequency band. With regard thereto, each of the one or more digital codes may be a code in which at least one second 5 bit which is a set number of lower bits is all 0 or 1. More specifically, when the one or more digital codes include a first digital code, a second digital code, and a third digital code, the first digital code and the second digital code may be codes in which at least one first bit is identical, and the first digital code and the third digital code may be codes in which at least one second bit is identical. For example, the first digital code may be a digital code in which at least one first bit is a first value and at least one second bit is all 0, and the second digital code may be a digital code in which at least one first bit is the first value and at least one second bit is all 1, and the third digital code may be a digital code in which at least one first bit is a value greater than the first value by 1 and at least one second bit is all 0, but example implementations are not limited thereto.

For example, when a digital code includes three bits, the plurality of digital codes may include eight digital codes, which are 000, 001, 010, 011, 100, 101, 110, and 111. In this case, a first bit among the three bits, the most significant bit (MSB), may be related to a first element, and the second bit and the third bit among the three bits may be related to a second element. With regard thereto, the first digital code may be 000, the second digital code may be 011, and the third digital code may be 100. In other words, the first bits of the first digital code and the second digital code may be identical as 0, and the second to third bits of the first digital code and the third digital code may be identical as 00. In addition, the value of the first bit of the third digital code, 1, may be greater by 1 than the value of the first bits of the first digital code and the second digital code, 0.

In some implementations, the digital code identifier 111 may transmit the one or more digital codes to the oscillator 120. Referring to FIG. 4, the digital code identifier 111 may transmit 000, the first digital code, among the one or more digital codes to the oscillator 120 first. Accordingly, the values of the plurality of elements included in the oscillator 120 may be adjusted to correspond to the digital code, 000, and the oscillator 120 may generate a clock signal of a frequency based on the plurality of elements having the adjusted values. Referring to FIG. 4, the oscillator 120 may generate a clock signal of 20 GHz. The counter 130 may calculate a first output value corresponding to the number of waveforms of a clock signal received from the oscillator 120, which is received for a set time (for example, 10 ns). The digital code identifier 111 may receive 200, the first output value, from the counter 130. A similar operation may be performed for the second digital code and the third digital code. Accordingly, the digital code identifier 111 may obtain an output value corresponding to each of the one or more digital codes outputted from the oscillator 120. A second output value corresponding to the second digital code may be 203 and a third output value corresponding to the third digital code may be 202.

In some implementations, the digital code identifier 111 may identify the at least one digital code by performing a predetermined computation based on the one or more digital codes and an output value outputted from the counter 130 in response to that a clock signal of a frequency based on the plurality of elements having values corresponding to each of the one or more digital codes is inputted to the counter 130. More specifically, the predetermined computation may be based on a difference between the second output value and the third output value and a difference between output values from the counter 130 for each unit bit. For example, when the number of at least one first bit which is an upper bit is 1, the predetermined computation may be represented as equation 1 below.

$$N = 1 + floor ( \frac{( {output}_{2} - {output}_{3} )}{resolution} ) , \qquad [ Equation 1 ]$$

$$resolution = \frac{{output}_{2} - {output}_{1}}{digital {code}_{2} - digital {code}_{1}}$$

Here, N may be the number of the at least one digital code corresponding to the overlapping frequency band. Resolution may be the difference between output values from the counter 130 for each unit bit. output₁ may be an output value outputted from the counter 130 corresponding to the first digital code, output₂ may be an output value outputted from the counter 130 corresponding to the second digital code, and output₃ may be an output value outputted from the counter 130 corresponding to the third digital code. In addition, digital code₁ may correspond to the first digital code and digital code₂ may correspond to the second digital code. With regard thereto, floor(x) may be a function that outputs the largest integer less than or equal to variable x. Referring to FIG. 4, since digital code₂ is 011₂ and digital code₁ is 000₂, digital code₂-digital code₁ may be calculated as 3, and resolution may be calculated as 1. Therefore, the number of the at least one digital code corresponding to the overlapping frequency band, N may be calculated as 2.

However, in example implementations of the present disclosure, the number of at least one first bit which is the upper bit is not limited to 1. When the number of at least one first bit which is the upper bit is 2 or more, the predetermined computation according to equation 1 may be similarly applied to a pair whose at least one first bit is different from one another by 1. For example, when the number of at least one first bit which is the upper bit is M, the predetermined computation may be represented as equation 2 below.

$$Total Number = {\sum }_{i = 1}^{{2}^{M} - 1} {N}_{i} \qquad [ Equation 2 ]$$

When the number of at least one first bit which is the upper bit is M, a pair whose at least one first bit is different from one another by 1 may be a total of 2^{M}−1. For example, when the number of at least one first bit which is the upper bit is 2, a first pair including 00 and 01, a second pair including 01 and 10, and a third pair including 10 and 11 may be three pairs whose at least one first bit is different from one another by 1. As the predetermined computation according to equation 1 is similarly performed for each of the three pairs, Total Number may be calculated.

In some implementations, based on an indicator of a quality of the oscillator 120 and a target frequency of the clock signal generator 100, the digital code identifier 111 may identify at least one digital code corresponding to the number according to that the predetermined computation is performed. More specifically, based on an indicator of a quality of the oscillator 120 and a target frequency of the clock signal generator 100, the digital code identifier 111 may identify a digital code for which the indicator of the quality of the oscillator 120 is relatively bad among digital codes included in an overlapping frequency band as at least one digital code to be a target of filtering. Here, the indicator of the quality of the oscillator 120 may be a Q factor of the oscillator 120 but is not limited thereto. When the oscillator 120 is an LC oscillator, the Q factor of an inductor may be low in a low-frequency band and the Q factor of a capacitor may be low in a high-frequency band. With regard thereto, when the target frequency is included in the high-frequency band, the at least one digital code may include a digital code corresponding to the capacitor with a relatively large value among digital codes included in the overlapping frequency band. Conversely, when the target frequency is included in the low-frequency band, the at least one digital code may include a digital code corresponding to the inductor with a relatively large value among digital codes included in the overlapping frequency band. Referring to FIG. 4, 20.2 GHz to 20.3 GHz may be determined as the overlapping frequency band, and the overlapping frequency band may be the high-frequency band. With regard thereto, 100 and 101 which are included in the at least one digital code may be digital codes corresponding to the capacitor with a relatively large value among digital codes included in the overlapping frequency band. The digital code identifier 111 may transmit information on the identified at least one digital code to the automatic frequency controller 112.

FIG. 5 is a diagram for illustrating an example of an operation of an automatic frequency controller in more detail.

In some implementations, the automatic frequency controller 112 may identify a plurality of first digital codes into which the at least one digital code is filtered from the plurality of digital codes. Referring to FIG. 5, the plurality of first digital codes may include 000, 001, 010, 011, 110, and 111.

In some implementations, the automatic frequency controller 112 may transmit at least some of the plurality of first digital codes in sequence to the oscillator 120. The automatic frequency controller 112 may transmit a start digital code to the oscillator 120 first. Here, the start digital code may be a preset digital code. For example, the start digital code may be a preset digital code to correspond to theoretical values of a plurality of elements for generating an output signal of a target frequency. For another example, values of bits included in the start digital code may be all 0 but are not limited thereto. For example, the start digital code may be identified based on the one or more digital codes of FIG. 4. More specifically, a digital code corresponding to a clock signal of a frequency close to a target frequency among the one or more digital codes may be identified as the start digital code. For example, when the target frequency is 20.42 GHz, the start digital code may be 011, a digital code for generating a clock signal of 20.3 GHz which is a frequency close to 20.42 GHz among the one or more digital codes. However, for various reasons such as a difference between the design and the actual production of a device including the oscillator 120, a change in standards according to a use period of an element including the oscillator 120, and a difference in temperature coefficient by element, a frequency of a clock signal generated in the oscillator 120 may be different from a theoretical prediction value, and thus an actual frequency based on a plurality of elements having values corresponding to a start digital code may be different from a target frequency.

Referring to FIG. 5, the digital code identifier 111 may transmit 001, a start digital code, among the plurality of first digital codes to the oscillator 120 first. Accordingly, values of a plurality of elements included in the oscillator 120 may be adjusted to correspond to the digital code 001, and the oscillator 120 may generate a clock signal of a frequency based on the plurality of elements having the adjusted values. Referring to FIG. 5, the oscillator 120 may generate a clock signal of 20.1 GHz. The counter 130 may calculate an output value corresponding to the number of waveforms of a clock signal received from the oscillator 120 which is received for a set time. The digital code identifier 111 may receive 201, an output value, from the counter 130.

In some implementations, the automatic frequency controller 112 may compare an output value outputted from the counter 130 corresponding to a digital code and a target value to be outputted in response to that a clock signal of a target frequency is inputted to the counter 130. When a result of the comparison indicates that the output value is within a set range from the target value, a corresponding digital code may be identified as a digital code corresponding to values of a plurality of elements for generating a clock signal of a frequency adjacent to the target frequency. More specifically, the output value within the set range from the target value may indicate that the frequency of the clock signal based on the plurality of elements having values corresponding to the corresponding digital code is within a lock range from the target frequency. Conversely, when the result of the comparison indicates that the output value is not within the set range from the target value, any one digital code among two digital codes adjacent to a corresponding digital code may be transmitted to the oscillator 120. As the operation of comparing output values corresponding to digital codes with target values is performed in sequence, when it is identified that an output value corresponding to a specific digital code is within a set range from a target value, the operation of the automatic frequency controller 112 may end. In this case, the specific digital code may be an end digital code, and a frequency of a clock signal based on a plurality of elements having values corresponding to the end digital code may be identified as an initial frequency.

In some implementations, the automatic frequency controller 112 may compare 201, an output value outputted from the counter 130 corresponding to the start digital code, and 204.2, a target value to be outputted in response to that a clock signal of 20.42 GHz, a target frequency, is inputted to the counter 130. In other words, since 201, the output value, is not within a set range (for example, within 0.5) from 204.2, the target value, the automatic frequency controller 112 may identify 000 and 010, two digital codes adjacent to the start digital code 001, and any one digital code among the two adjacent digital codes may be transmitted to the oscillator 120. With regard thereto, in order to control a frequency of a clock signal generated in the oscillator 120 to be higher, the automatic frequency controller 112 may transmit the digital code 010 among the two adjacent digital codes to the oscillator 120. As a similar operation is performed repeatedly, the automatic frequency controller 112 may transmit 001, 010, 011, and 110 among the plurality of first digital codes in sequence to the oscillator 120. The automatic frequency controller 112 may compare 204, an output value outputted from the counter 130 corresponding to the digital code 110, and 204.2, the target value to be outputted in response to that the clock signal of the target frequency is inputted to the counter 130. Since 204, the output value, is within the set range from 204.2, the target value, the operation of the automatic frequency controller 112 may end. Further, the digital code 110 may be determined as an end digital code, and 20.4 GHz, a frequency of a clock signal based on a plurality of elements having values corresponding to the end digital code, may be determined as an initial frequency.

In other words, by transmitting 001, 010, 011, and 110 alone, which are at least some of the plurality of first digital codes, excluding 100 and 101, which are digital codes corresponding to an overlapping frequency band, in sequence to the oscillator 120, the automatic frequency controller 112 may rapidly identify a digital code corresponding to a clock signal of a frequency within a lock range from a target frequency.

FIG. 6 is a diagram for illustrating an example of an operation of an oscillator controller in more detail.

In some implementations, the oscillator controller 140 may be a device for controlling the oscillator 120 so that a frequency of a clock signal generated in the oscillator 120 is a target frequency. A plurality of elements included in the oscillator 120 may have values corresponding to an end digital code. The oscillator controller 140 may include a frequency detector, a charge pump, a loop filter, and a frequency divider but is not limited thereto.

In some implementations, the oscillator controller 140 may transmit a control signal (for example, CTRL) for controlling a frequency generated in the oscillator 120 to the oscillator 120. More specifically, the oscillator controller 140 may transmit a control signal for controlling the frequency generated in the oscillator 120 to be close to a target frequency to the oscillator 120 by using a clock signal generated in the oscillator 120 as feedback. As the oscillator controller 140 operates, the frequency of the clock signal generated in the oscillator 120 may be synchronized with the target frequency.

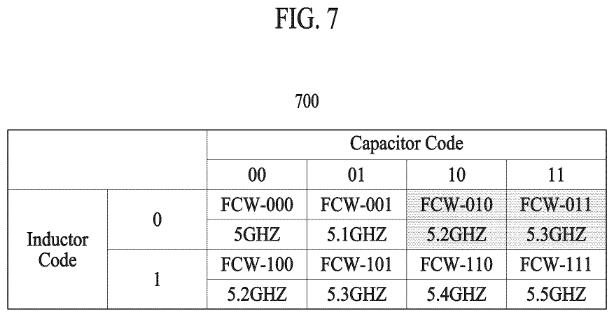

FIG. 7 is a diagram for illustrating an example of a table that indicates a plurality of digital codes and a frequency of a clock signal corresponding to each of the plurality of digital codes when a target frequency is included in a low-frequency band.

Referring to FIG. 7, when each of a plurality of digital codes includes three bits, a table 700 may indicate the plurality of digital codes and a frequency of a clock signal corresponding to each of the plurality of digital codes. The MSB, the first bit among the three bits, may be related to an inductor, and the second bit and the third bit among the three bits may be related to a capacitor. In other words, a value of an inductor included in the oscillator 120 may be adjusted depending on a value of the MSB, and a value of a capacitor included in the oscillator 120 may be adjusted depending on values of the second bit and the third bit. With regard thereto, values of a plurality of elements may be set such that a frequency based on the plurality of elements changes by a second value when at least one second bit of a digital code changes by a first value. Referring to FIG. 7, the plurality of digital codes may be set such that a frequency based on a plurality of elements changes by 0.1 GHz when at least one second bit changes by 1 with at least one first bit fixed.

One or more digital codes used to identify at least one digital code corresponding to an overlapping frequency band among the plurality of digital codes may include a first digital code 000, a second digital code 011, and a third digital code 100. A first output value outputted from the counter 130 corresponding to the first digital code 000 may be 50, a second output value outputted from the counter 130 corresponding to the second digital code 011 may be 53, and a third output value outputted from the counter 130 corresponding to the third digital code 100 may be 52. In other words, 5.2 GHz to 5.3 GHz may be identified as the overlapping frequency band, and the number of digital codes corresponding to the overlapping frequency band may be calculated as 2 based on equation 1.

In some implementations, the at least one digital code may be identified based on an indicator of a quality of the oscillator 120 and a target frequency of the clock signal generator 100. A digital code included in the overlapping frequency band may be classified into two groups based on a value of at least one first bit. A first group including the second digital code may be a group in which a value of at least one second bit is relatively large and a value of at least one first bit is relatively small. In other words, the first group may be a group in which a value of a capacitor is relatively small and a value of an inductor is relatively large. Conversely, a second group including the third digital code may be a group in which a value of at least one second bit is relatively small and a value of at least one first bit is relatively large. In other words, the second group may be a group in which a value of a capacitor is relatively large and a value of an inductor is relatively small. With regard thereto, the at least one digital code may correspond to any one of the first group and the second group. For example, the target frequency and the overlapping frequency band may be included in a low-frequency band. Further, since a Q factor of a capacitor may be high and a Q factor of an inductor may be low in the low-frequency band, a Q factor of the oscillator 120 may be calculated to be high as the value of the capacitor is large. In other words, the at least one digital code may include the digital codes 010 and 011 corresponding to the first group in which the value of the capacitor is relatively small.

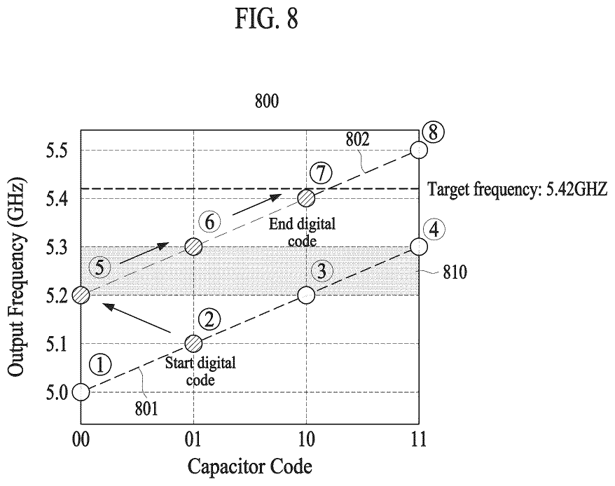

FIG. 8 is a graph for illustrating an example of a manner of identifying an end digital code for generating a clock signal of a frequency within a set range from a target frequency as increasing a value of a digital code.

Referring to FIG. 8, a graph 800 may indicate a frequency of a clock signal corresponding to each of the plurality of digital codes according to FIG. 7. For example, a line 801 may indicate frequencies of clock signals corresponding to digital codes with the first bit of 0 and a line 802 may indicate frequencies of clock signals corresponding to digital codes with the first bit of 1. A start digital code may be 001 and a target frequency may be 5.42 GHz. In addition, the digital codes 010 and 011 among digital codes 010, 011, 100, and 101 included in an overlapping frequency band 810 may be included in at least one digital code to be a target of filtering.

In some implementations, the automatic frequency controller 112 may transmit at least some of the plurality of first digital codes in sequence to the oscillator 120. The automatic frequency controller 112 may compare an output value outputted from the counter in response to that a clock signal of a frequency corresponding to a digital code is inputted to the counter 130 and a target value to be outputted from the counter in response to that a clock signal of a target frequency is inputted to the counter 130. When a result of the comparison indicates that the output value is less than the target value by a set value (for example, 0.5) or more, the automatic frequency controller 112 may identify any one digital code among two digital codes adjacent to the digital code so that a frequency of a clock signal generated in the oscillator 120 is higher.

For example, the automatic frequency controller 112 may transmit 001, the start digital code, to the oscillator 120. When a result of the comparison according thereto indicates that 51, the output value, is less than 54.2, the target value, by the set value or more, the automatic frequency controller 112 may identify 100 among two adjacent digital codes, 000 and 100, so that a frequency of a clock signal generated in the oscillator 120 is higher. Then, the automatic frequency controller 112 may transmit the digital code 100 to the oscillator 120. A similar operation may be performed for the digital code 100 and the digital code 101, and accordingly the automatic frequency controller 112 may transmit the digital code 110 to the oscillator 120. When a result of the comparison according thereto indicates that 54, the output value corresponding to the digital code 110, is within the set range from 54.2, the target value, the digital code 110 may be identified as an end digital code. The operation of the automatic frequency controller 112 may end. In other words, the automatic frequency controller 112 may efficiently identify a digital code for generating an output signal of a frequency close to a target frequency while not transmitting the digital codes 010 and 011 among digital codes included in the overlapping frequency band 810 to the oscillator 120.

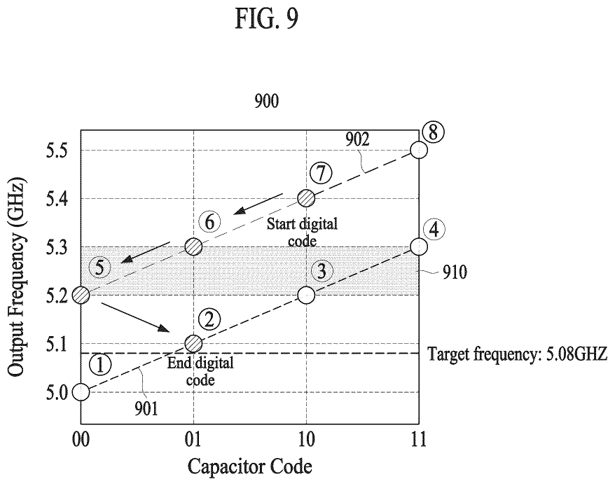

FIG. 9 is a graph for illustrating an example of a manner of identifying an end digital code for generating a clock signal of a frequency within a set range from a target frequency as decreasing a value of a digital code.

Referring to FIG. 9, a graph 900 may indicate a frequency of a clock signal corresponding to each of the plurality of digital codes according to FIG. 7. For example, a line 901 may indicate frequencies of clock signals corresponding to digital codes with the first bit of 0 and a line 902 may indicate frequencies of clock signals corresponding to digital codes with the first bit of 1. A start digital code may be 110 and a target frequency may be 5.08 GHz. In addition, the digital codes 010 and 011 among digital codes 010, 011, 100, and 101 included in an overlapping frequency band 910 may be included in at least one digital code to be a target of filtering.

In some implementations, the automatic frequency controller 112 may transmit at least some of the plurality of first digital codes in sequence to the oscillator 120. The automatic frequency controller 112 may compare an output value outputted from the counter in response to that a clock signal of a frequency corresponding to a digital code is inputted to the counter 130 and a target value to be outputted from the counter in response to that a clock signal of a target frequency is inputted to the counter 130. When a result of the comparison indicates that the output value is greater than the target value by a set value (for example, 0.5) or more, the automatic frequency controller 112 may identify any one digital code among two digital codes adjacent to the digital code so that a frequency of a clock signal generated in the oscillator 120 is lower.

For example, the automatic frequency controller 112 may transmit the start digital code to the oscillator 120. When a result of the comparison according thereto indicates that 54, the output value, is greater than 50.8, the target value, by the set value or more, the automatic frequency controller 112 may identify 101 among two adjacent digital codes, 101 and 111, so that a frequency of a clock signal generated in the oscillator 120 is lower. Then, the automatic frequency controller 112 may transmit the digital code 101 to the oscillator 120. A similar operation may be performed for the digital codes 101 and 100, and accordingly the automatic frequency controller 112 may transmit the digital code 001 to the oscillator 120. When a result of the comparison according thereto indicates that 51, the output value corresponding to the digital code 001, is within the set range from 50.8, the target value, the digital code 001 may be identified as an end digital code. The operation of the automatic frequency controller 112 may end. In other words, the automatic frequency controller 112 may efficiently identify a digital code for generating an output signal of a frequency close to a target frequency while not transmitting the digital codes 010 and 011 among digital codes included in the overlapping frequency band 910 to the oscillator 120.

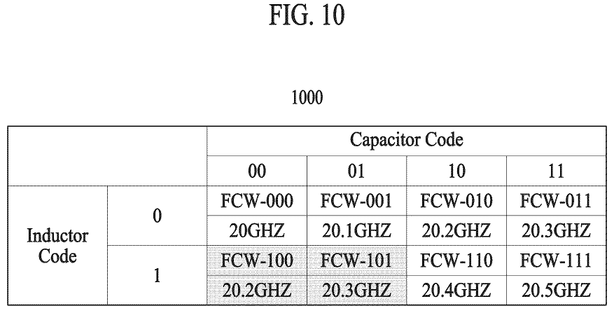

FIG. 10 is a diagram for illustrating an example of a table that indicates a plurality of digital codes and a frequency of a clock signal corresponding to each of the plurality of digital codes when a target frequency is included in a high-frequency band.

Referring to FIG. 10, when each of a plurality of digital codes includes three bits, a table 1000 may indicate the plurality of digital codes and a frequency of a clock signal corresponding to each of the plurality of digital codes. With regard thereto, the MSB, the first bit among the three bits, may be related to an inductor, and the second bit and the third bit among the three bits may be related to a capacitor. In other words, a value of an inductor included in the oscillator 120 may be adjusted depending on a value of the MSB, and a value of a capacitor included in the oscillator 120 may be adjusted depending on values of the second bit and the third bit.

One or more digital codes used to identify at least one digital code corresponding to an overlapping frequency band among the plurality of digital codes may include a first digital code 000, a second digital code 011, and a third digital code 100. A first output value outputted from the counter 130 corresponding to the first digital code 000 may be 200, a second output value outputted from the counter 130 corresponding to the second digital code 011 may be 203, and a third output value outputted from the counter 130 corresponding to the third digital code 100 may be 202. In other words, 20.2 GHz to 20.3 GHz may be identified as the overlapping frequency band, and the number of digital codes corresponding to the overlapping frequency band may be calculated as 2 based on equation 1.

In some implementations, the at least one digital code may be identified based on an indicator of a quality of the oscillator 120 and a target frequency of the clock signal generator 100. As described, a digital code included in the overlapping frequency band may be classified into two groups based on a value of at least one first bit. A first group including the second digital code may be a group in which a value of at least one second bit is relatively large and a value of at least one first bit is relatively small. In other words, the first group may be a group in which a value of a capacitor is relatively small and a value of an inductor is relatively large. Conversely, a second group including the third digital code may be a group in which a value of at least one second bit is relatively small and a value of at least one first bit is relatively large. In other words, the second group may be a group in which a value of a capacitor is relatively large and a value of an inductor is relatively small. With regard thereto, the at least one digital code may correspond to any one of the first group and the second group. The target frequency and the overlapping frequency band may be included in a high-frequency band. Further, since a Q factor of a capacitor may be low and a Q factor of an inductor may be high in the high-frequency band, a Q factor of the oscillator 120 may be calculated to be high as the value of the inductor is large. In other words, the at least one digital code may include the digital codes 100 and 101 corresponding to the second group in which the value of the inductor is relatively small.

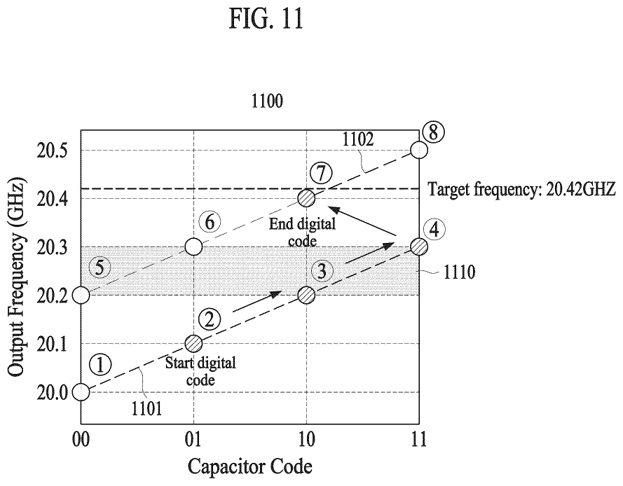

FIG. 11 is a graph for illustrating an example of a manner of identifying an end digital code for generating a clock signal of a frequency within a set range from a target frequency as increasing a value of a digital code.

Referring to FIG. 11, a graph 1100 may indicate a frequency of a clock signal corresponding to each of the plurality of digital codes according to FIG. 10. For example, a line 1101 may indicate frequencies of clock signals corresponding to digital codes with the first bit of 0 and a line 1102 may indicate frequencies of clock signals corresponding to digital codes with the first bit of 1. A start digital code may be 001 and a target frequency may be 20.42 GHz. In addition, the digital codes 100 and 101 among digital codes 010, 011, 100, and 101 included in an overlapping frequency band 1110 may be included in at least one digital code to be a target of filtering.

In some implementations, the automatic frequency controller 112 may transmit at least some of the plurality of first digital codes in sequence to the oscillator 120. The automatic frequency controller 112 may compare an output value outputted from the counter in response to that a clock signal of a frequency corresponding to a digital code is inputted to the counter 130 and a target value to be outputted from the counter in response to that a clock signal of a target frequency is inputted to the counter 130. When a result of the comparison indicates that the output value is less than the target value by a set value (for example, 0.5) or more, the automatic frequency controller 112 may identify any one digital code among two digital codes adjacent to the digital code so that a frequency of a clock signal generated in the oscillator 120 is higher.

For example, the automatic frequency controller 112 may transmit the start digital code to the oscillator 120. When a result of the comparison according thereto indicates that 201, the output value, is less than 204.2, the target value, by the set value or more, the automatic frequency controller 112 may identify 010 among two adjacent digital codes, 000 and 010, so that a frequency of a clock signal generated in the oscillator 120 is higher. Then, the automatic frequency controller 112 may transmit the digital code 010 to the oscillator 120. A similar operation may be performed for the digital codes 010 and 011, and accordingly the automatic frequency controller 112 may transmit the digital code 110 to the oscillator 120. When a result of the comparison according thereto indicates that 204, the output value corresponding to the digital code 110, is within the set range from 204.2, the target value, the digital code 110 may be identified as an end digital code. The operation of the automatic frequency controller 112 may end. In other words, the automatic frequency controller 112 may efficiently identify a digital code for generating an output signal of a frequency close to a target frequency while not transmitting the digital codes 100 and 101 among digital codes included in the overlapping frequency band 1110 to the oscillator 120.

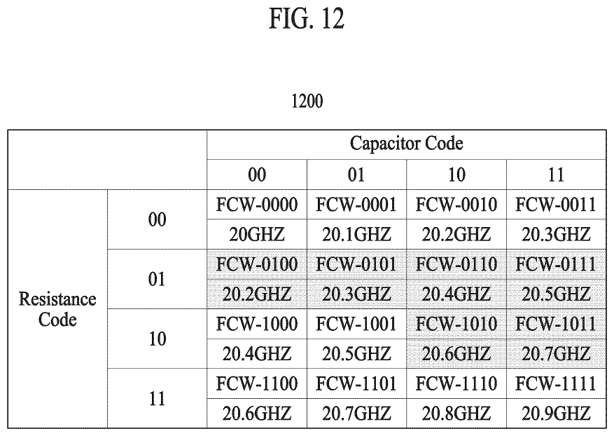

FIG. 12 is a diagram for illustrating an example of a table that indicates a plurality of digital codes and a frequency of a clock signal corresponding to each of the plurality of digital codes when a plurality of upper bits related to a first element are provided.

Referring to FIG. 12, when each of a plurality of digital codes includes four bits, a table 1200 may indicate the plurality of digital codes and a frequency of a clock signal corresponding to each of the plurality of digital codes. In FIG. 12, the oscillator 120 may be an RC oscillator. With regard thereto, the first bit and the second bit among the four bits may be related to resistance, and the third bit and the fourth bit among the four bits may be related to a capacitor. In other words, a value of resistance included in the oscillator 120 may be adjusted depending on values of the first bit and the second bit, and a value of a capacitor included in the oscillator 120 may be adjusted depending on values of the third bit and the fourth bit.

In some implementations, one or more digital codes used to identify at least one digital code corresponding to an overlapping frequency band among the plurality of digital codes may be classified into three groups. A first group may include 0000, 0011, and 0100, a second group may include 0100, 0111, and 1000, and a third group may include 1000, 1011, and 1100. For each group, the number of digital codes used to identify at least one digital code corresponding to the overlapping frequency band may be determined through a predetermined computation based on equation 1. Since a detailed manner of identifying at least one digital code for each group is similar to the manner of identifying at least one digital code of FIGS. 3, 7, and 10, duplicate descriptions with FIGS. 3, 7, and 10 are omitted. With regard thereto, the at least one digital code may be identified based on an indicator of a quality of the oscillator 120 and a target frequency of the clock signal generator 100. Referring to FIG. 12, the at least one digital code may include 0100, 0101, 0110, 0111, 1010, and 1011.

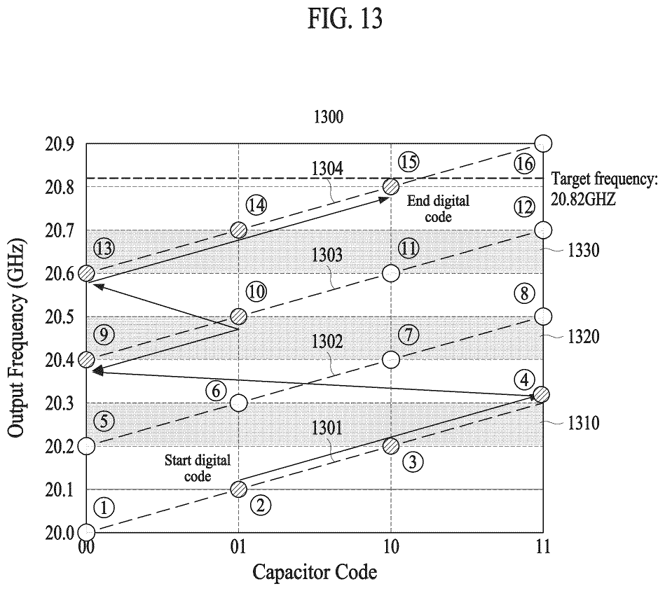

FIG. 13 is a graph for illustrating an example of a manner of identifying an end digital code for generating a clock signal of a frequency within a set range from a target frequency as increasing a value of a digital code when a plurality of overlapping frequency bands are provided.

Referring to FIG. 13, a graph 1300 may indicate a frequency of a clock signal corresponding to each of the plurality of digital codes according to FIG. 12. For example, a line 1301 may indicate frequencies of clock signals corresponding to digital codes with the first bit of 0 and the second bit of 0. A line 1302 may indicate frequencies of clock signals corresponding to digital codes with the first bit of 0 and the second bit of 1. A line 1303 may indicate frequencies of clock signals corresponding to digital codes with the first bit of 1 and the second bit of 0. In addition, a line 1304 may indicate frequencies of clock signals corresponding to digital codes with the first bit of 1 and the second bit of 1. A start digital code may be 0001 and a target frequency may be 20.82 GHz. The digital codes 0100 and 0101 among digital codes 0010, 0011, 0100, and 0101 included in an overlapping frequency band 1310 may be included in at least one digital code to be a target of filtering. The digital codes 0110 and 0111 among digital codes 0110, 0111, 1000, and 1001 included in an overlapping frequency band 1320 may be included in at least one digital code to be a target of filtering. Further, the digital codes 1010 and 1011 among digital codes 1010, 1011, 1100, and 1101 included in an overlapping frequency band 1330 may be included in at least one digital code to be a target of filtering. In other words, a plurality of first digital codes may include 0000, 0001, 0010, 0011, 1000, 1001, 1100, 1101, 1110, and 1111.

In some implementations, the automatic frequency controller 112 may transmit at least some of the plurality of first digital codes in sequence to the oscillator 120. The automatic frequency controller 112 may compare an output value outputted from the counter in response to that a clock signal of a frequency corresponding to a digital code is inputted to the counter 130 and a target value to be outputted from the counter in response to that a clock signal of a target frequency is inputted to the counter 130. When a result of the comparison indicates that the output value is less than the target value by a set value (for example, 0.5) or more, the automatic frequency controller 112 may identify any one digital code among two digital codes adjacent to the digital code so that a frequency of a clock signal generated in the oscillator 120 is higher.

For example, the automatic frequency controller 112 may transmit 0001, the start digital code, to the oscillator 120. When a result of the comparison according thereto indicates that 201, the output value, is less than 208.2, the target value, by the set value or more, the automatic frequency controller 112 may identify 0010 among two adjacent digital codes, 0000 and 0010, so that a frequency of a clock signal generated in the oscillator 120 is higher. Then, the automatic frequency controller 112 may transmit the digital 0010 to the oscillator 120. A similar operation may be performed for the digital codes 0010, 0011, 1000, 1001, 1100, and 1101, and accordingly the automatic frequency controller 112 may transmit the digital code 1110 to the oscillator 120. When a result of the comparison according thereto indicates that 208, the output value corresponding to the digital code 1110, is within the set range from 208.2, the target value, the digital code 1110 may be identified as an end digital code. The operation of the automatic frequency controller 112 may end. In other words, the automatic frequency controller 112 may efficiently identify a digital code for generating an output signal of a frequency close to a target frequency while not transmitting the digital codes 0100, 0101, 0110, 0111, 1010, and 1011 among digital codes included in the overlapping frequency bands 1310, 1320, and 1330 to the oscillator 120.

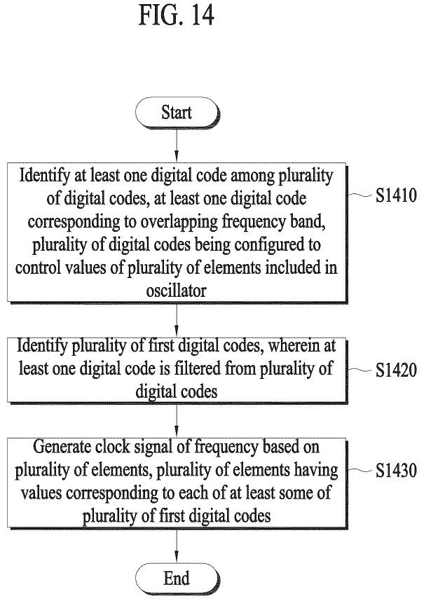

FIG. 14 is a flowchart for illustrating an example of an operation method of a clock signal generator.

Since each operation of the operation method of FIG. 14 may be performed by the clock signal generator 100 described above, duplicate descriptions with FIGS. 1 to 13 are omitted. Here, the clock signal generator 100 may include the frequency calibrator 110 and the oscillator 120.

In operation S1410, the clock signal generator 100 may identify at least one digital code among a plurality of digital codes, the at least one digital code corresponding to an overlapping frequency band, the plurality of digital codes being configured to control values of a plurality of elements included in an oscillator 120. More specifically, the digital code identifier 111 included in the clock signal generator 100 may identify the one or more digital codes among the plurality of digital codes for controlling the values of the plurality of elements included in the oscillator 120. In addition, the digital code identifier 111 may identify the at least one digital code corresponding to the overlapping frequency band based on the one or more digital codes and an output value outputted from the counter 130 in response to that a clock signal of a frequency based on the plurality of elements having values corresponding to each of the one or more digital codes is inputted to the counter 130.

In operation S1420, the clock signal generator 100 may identify a plurality of first digital codes, wherein the at least one digital code is filtered from the plurality of digital codes. More specifically, the automatic frequency controller 112 included in the clock signal generator 100 may identify the plurality of first digital codes into which the at least one digital code is filtered from the plurality of digital codes and transmit at least some of the plurality of first digital codes to the oscillator 120.

In operation S1430, the clock signal generator 100 may generate a clock signal of a frequency based on the plurality of elements, the plurality of elements having values corresponding to each of at least some of the plurality of first digital codes. More specifically, the oscillator 120 included in the clock signal generator 100 may generate the clock signal of the frequency based on the plurality of elements having values corresponding to each of at least some of the plurality of first digital codes.

The clock signal generator 100 or the frequency calibrator 110 according to the above-described example implementations may include a processor, a memory for storing and executing program data, a permanent storage such as a disk drive, a communication port that communicates with an external device, and a user interface device such as a touch panel, a key, and a button. Methods implemented as software modules or algorithms may be stored in a computer-readable recording medium as computer-readable codes or program instructions executable on the processor. Here, the computer-readable recording medium includes a magnetic storage medium (for example, read-only memory (ROM), random-access memory (RAM), floppy disks, and hard disks) and an optically readable medium (for example, CD-ROM and digital versatile discs (DVDs)). The computer-readable recording medium may be distributed among network-connected computer systems, so that the computer-readable codes may be stored and executed in a distributed manner. The medium may be readable by a computer, stored in a memory, and executed on a processor.

The example implementations may be represented by functional block elements and various processing steps. The functional blocks may be implemented in any number of hardware and/or software configurations that perform specific functions. For example, an example implementation may adopt integrated circuit configurations, such as memory, processing, logic, and/or look-up table, that may execute various functions by the control of one or more microprocessors or other control devices. Similarly to that elements may be implemented as software programming or software elements, the example implementations may be implemented in a programming or scripting language such as C, C++, Java, assembler, etc., including various algorithms implemented as a combination of data structures, processes, routines, or other programming constructs. Functional aspects may be implemented in an algorithm running on one or more processors. Further, the example implementations may adopt the existing art for electronic environment setting, signal processing, and/or data processing. Terms such as “mechanism,” “element,” “means,” and “configuration” may be used broadly and are not limited to mechanical and physical elements. The terms may include the meaning of a series of routines of software in association with a processor or the like.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The above-described example implementations are merely examples, and other example implementations may be implemented within the scope of the claims to be described later.

What is claimed is:

1. A clock signal generator comprising:
an oscillator; and
a frequency calibrator configured to
identify at least one digital code among a plurality of digital codes, the at least one digital code corresponding to an overlapping frequency band, the plurality of digital codes being configured to control values of a plurality of elements included in the oscillator, and
identify a plurality of first digital codes, wherein the at least one digital code is filtered from the plurality of digital codes; and
wherein the oscillator is configured to generate a clock signal of a frequency based on the plurality of elements, the plurality of elements having values corresponding to each of at least some of the plurality of first digital codes.

2. The clock signal generator of claim 1, wherein the plurality of elements include a first element and a second element, and
wherein each of the plurality of digital codes includes at least one first bit related to the first element and at least one second bit related to the second element.

3. The clock signal generator of claim 2, wherein, based on the oscillator being an LC oscillator, the first element is an inductor, and the second element is a capacitor, and
wherein, based on the oscillator being an RC oscillator, the first element is resistance, and the second element is a capacitor.

4. The clock signal generator of claim 1, wherein the clock signal generator is configured to generate a clock signal of a target frequency, the target frequency being equal to or higher than a first set value.

5. The clock signal generator of claim 2, comprising a counter configured to output a number of waveforms of the clock signal received within a set time,
wherein the frequency calibrator is configured to identify the at least one digital code based on performing a predetermined computation, the predetermined computation being performed based on one or more digital codes and an output value, the output value being outputted from the counter based on the clock signal of the frequency being inputted to the counter, the clock signal of the frequency being based on the plurality of elements having values corresponding to each of the one or more digital codes.

6. The clock signal generator of claim 5, wherein the one or more digital codes include a first digital code, a second digital code, and a third digital code,
wherein the at least one first bit of the first digital code is the same as the at least one first bit of the second digital code, and
wherein the at least one second bit of the first digital code is the same as the at least one second bit of the third digital code.

7. The clock signal generator of claim 6, wherein a first output value is outputted from the counter based on a first clock signal of a first frequency being inputted to the counter, the first clock signal of the first frequency being based on the plurality of elements having values corresponding to the first digital code,
wherein a second output value is outputted from the counter based on a second clock signal of a second frequency being inputted to the counter, the second clock signal of the second frequency being based on the plurality of elements having values corresponding to the second digital code,
wherein a third output value is outputted from the counter based on a third clock signal of a third frequency being inputted to the counter, the third clock signal of the third frequency being based on the plurality of elements having values corresponding to the third digital code, and
wherein the predetermined computation is based on a first difference between the second output value and the third output value and a second difference between output values from the counter for each unit bit based on the first digital code, the second digital code, the first output value, and the second output value.

8. The clock signal generator of claim 6, wherein the frequency calibrator is configured to identify the at least one digital code based on an indicator of a quality of the oscillator and a target frequency of the clock signal generator.

9. The clock signal generator of claim 8, wherein the at least one digital code includes a digital code between the second digital code and the third digital code.

10. The clock signal generator of claim 2, wherein the values of the plurality of elements are set such that, based on the at least one second bit changing by a first value, the frequency based on the plurality of elements changes by a second value.

11. The clock signal generator of claim 4, comprising a counter configured to output a number of times that a waveform of the clock signal is received within a set time,
wherein the oscillator is configured to generate a clock signal of a fourth frequency based on the plurality of elements having values corresponding to a fourth digital code received from the frequency calibrator, and
wherein the frequency calibrator is configured to compare a fourth output value and a target value, the fourth output value being outputted from the counter based on the clock signal of the fourth frequency being inputted to the counter, the target value to be outputted based on the clock signal of the target frequency being inputted to the counter.

12. The clock signal generator of claim 11, wherein the frequency calibrator is configured to
identify a fifth digital code and a sixth digital code that are adjacent to the fourth digital code among the plurality of first digital codes, and
transmit a digital code between the fifth digital code and the sixth digital code to the oscillator based on a result of the comparison.

13. The clock signal generator of claim 12, wherein the frequency calibrator is configured to, based on the result of the comparison indicating that the fourth output value is greater than the target value by a second set value or more, identify one digital code between the fifth digital code and the sixth digital code so that a frequency of a clock signal generated in the oscillator is lower than the fourth frequency.

14. The clock signal generator of claim 12, wherein the frequency calibrator is configured to, based on the result of the comparison indicating that the fourth output value is less than the target value by a third set value or more, identify one digital code between the fifth digital code and the sixth digital code so that a frequency of a clock signal generated in the oscillator is higher than the fourth frequency.

15. The clock signal generator of claim 11, wherein, based on a result of the comparison indicating that the fourth output value is within a set range from the target value, the fourth digital code is a digital code corresponding to values of the plurality of elements that generate a clock signal of a frequency adjacent to the target frequency.

16. The clock signal generator of claim 15, comprising an oscillator controller configured to control the oscillator so that a frequency of a clock signal generated in the oscillator is a target frequency, the clock signal generated in the oscillator including the plurality of elements having values corresponding to the fourth digital code.

17. A frequency calibrator comprising:
a digital code identifier configured to
identify at least one digital code based on one or more digital codes and an output value among a plurality of digital codes, the plurality of digital codes being configured to control values of a plurality of elements included in an oscillator, the at least one digital code corresponding to an overlapping frequency band, the output value being outputted from a counter based on a clock signal of a frequency being inputted to the counter, the clock signal of the frequency being based on the plurality of elements having values corresponding to each of the one or more digital codes; and
an automatic frequency controller configured to
identify a plurality of first digital codes, wherein the at least one digital code is filtered from the plurality of digital codes, and
transmit at least some of the plurality of first digital codes to the oscillator.

18. An operation method of a clock signal generator, the operation method comprising:
identifying at least one digital code among a plurality of digital codes, the at least one digital code corresponding to an overlapping frequency band, the plurality of digital codes being configured to control values of a plurality of elements included in an oscillator;
identifying a plurality of first digital codes, wherein the at least one digital code is filtered from the plurality of digital codes; and
generating a clock signal of a frequency based on the plurality of elements, the plurality of elements having values corresponding to each of at least some of the plurality of first digital codes.

19. The operation method of claim 18, wherein the plurality of elements include a first element and a second element, and
wherein each of the plurality of digital codes includes at least one first bit related to the first element and at least one second bit related to the second element.

20. The operation method of claim 19, wherein the identifying of the at least one digital code comprises identifying the at least one digital code based on performing a predetermined computation, the predetermined computation being performed based on one or more digital codes and an output value, the output value being outputted from the counter based on the clock signal of the frequency being inputted to the counter, the clock signal of the frequency being based on the plurality of elements having values corresponding to each of the one or more digital codes.
